(19) United States
(12) Patent Application Publication
(10) Pub. No.: US 2026/0219581 A1
(43) Pub. Date: Jul. 30, 2026

(54) ILLUMINATION OPTICAL UNIT, AND METHOD FOR MEASURING A DEPENDENCE OF AN INTENSITY OF ILLUMINATION LIGHT, INCIDENT ON AN OBJECT FIELD, ON AT LEAST ONE DETECTION OBJECT FIELD COORDINATE USING SUCH AN ILLUMINATION OPTICAL UNIT

(71) Applicant: Carl Zeiss SMT GmbH, Oberkochen (DE)

(72) Inventors: Martin ENDRES, Königsbronn (DE); Michael RAMOLLA, Oberkochen (DE)

(21) Appl. No.: 19/629,618

(22) Filed: Mar. 26, 2026

Related U.S. Application Data
(63) Continuation of application No. PCT/EP2024/075914, filed on Sep. 17, 2024.

(30) Foreign Application Priority Data
Oct. 4, 2023 (DE) 10 2023 209 697.8

(51) Int. Cl. G03F 7/00

(52) U.S. Cl. CPC G03F 7/70133; G03F 7/70075; G03F 7/70116; G03F 7/7085

(57) ABSTRACT

An illumination optical unit has two facet mirrors for reflectively guiding illumination light from an EUV light source. The second facet mirror has second individual mirrors forming second facets which, via partial beams of the illumination light, image individual-mirror groups of the first facet mirror forming first facets at least into partial fields of an object field. An intensity sensor device serves for measuring a dependence of an intensity of the illumination light incident on the object field on at least one detection object field coordinate. The intensity sensor device has sensor individual mirrors of the first facet mirror which are assigned to a plurality of different object field positions along the detection object field coordinate. The sensor individual mirrors are designed for reflectively guiding the illumination light to intensity sensors of the intensity sensor device.

### CROSS-REFERENCE TO RELATED APPLICATIONS

The present application is a continuation of, and claims benefit under 35 USC 120 to, international application No. PCT/EP2024/075914, filed September 17, 2024, which claims benefit under 35 USC 119 of German Application No. 10 2023 209 697.8, filed October 4, 2023. The entire disclosure of each of these applications is incorporated by reference herein.

### FIELD

The disclosure relates to an illumination optical unit comprising two facet mirrors. Furthermore, the disclosure relates to a method for measuring a dependence of an intensity of illumination light incident on an object field on at least one detection object field coordinate using such an illumination optical unit.

### BACKGROUND

An illumination optical unit is known from DE 10 2015 208 512 A1.

### SUMMARY

The present disclosure seeks to develop an illumination optical unit and a measuring method therefor such that a measurement of a dependence of an intensity of illumination light incident on the object field on at least one detection object field coordinate is possible relatively precisely and/or in parallel to a utility or used operation of the illumination optical unit.

In an aspect, the disclosure provides an illumination optical unit, comprising: a first facet mirror comprising first individual mirrors for reflectively guiding illumination light from an EUV light source and for arrangement in a used region of an illumination light far field; a second facet mirror for reflectively guiding the illumination light reflected off the first facet mirror to an object field in which an object to be illuminated is arrangeable. The second facet mirror has second individual mirrors forming second facets which, via partial beams of the illumination light, image individual-mirror groups of the first facet mirror gorming first facets at least into partial fields of the object field. The illumination optical unit further comprises an intensity sensor device for measuring a dependence of an intensity of the illumination light incident on the object field on at least one detection object field coordinate. The intensity sensor device has: a plurality of the first individual mirrors constituting sensor individual mirrors of the first facet mirror, wherein the sensor individual mirrors are assigned to a plurality of different object field positions along the detection object field coordinate; and a plurality of intensity sensors, wherein the sensor individual mirrors are designed for reflectively guiding the illumination light to the intensity sensors.

The disclosure discloses that it has been recognized that, in the case of illumination optical units comprising two facet mirrors, for example in the case of illumination optical units in which at least one of the two facet mirrors is designed as a MEMS mirror comprising a very large number of individual mirrors, the great flexibility in the assignment of the individual mirrors of the two facet mirrors for guiding the illumination light within the illumination optical unit can regularly have the consequence that specific individual mirrors of the first facet mirror are not used for projection exposure within the illumination optical unit. In the case of the illumination optical unit according to the disclosure, illumination light incident on these individual mirrors of the first facet mirror can be used for measuring a dependence of an intensity of illumination light incident on an object field on at least one detection object field coordinate. This makes use of the insight that the individual mirrors of the first facet mirror which are not used for object field illumination, on account of their arrangement on the first facet mirror, allow a conclusion to be drawn about which object field coordinate is illuminated by individual mirrors which are used for projection exposure and which are adjacent to these sensor individual mirrors along the detection object field coordinate to be measured. This insight, which allows an assignment of the respective sensor individual mirrors to the object field coordinate to be detected, and the insight that a far field illumination intensity dependence over the first facet mirror regularly, as viewed over the dimension of an individual mirror, changes only slightly, lead to the possibility, with the aid of the intensity sensor device of the illumination optical unit, firstly of performing a relatively precise measurement of the dependence of the illumination intensity on the detection object field coordinate and secondly to the possibility of carrying out the measurement in parallel with the used operation of the illumination optical unit.

By way of the assignment of the first facets to the second facets, it is possible to specify for example an illumination setting, i.e. an illumination angle distribution of the illumination of the object field. The illumination intensity distribution over the object field coordinate to be detected may be dependent on the selected illumination setting and it may therefore be desirable to monitor this illumination intensity distribution in a setting-dependent manner, and if appropriate to correct it.

Even short-term intensity changes can be recognized, and if appropriate corrected, as part of ongoing monitoring with the intensity sensor device during used operation.

The illumination optical unit can be designed with a field facet mirror and a pupil facet mirror, in which the second facet mirror is arranged in the region of a pupil plane of the illumination optical unit. Alternatively, the illumination optical unit can also be designed in the manner of a specular reflector, in which the second facet mirror is arranged at a distance from an illumination pupil plane.

The intensity sensor device can be used for example as a field-resolving UNICOM sensor. By way of the intensity sensor device, it is then possible to control a corresponding device for influencing a uniformity of an illumination intensity over the field height. Such an influencing device, which is also known under the designation UNICOM, is known from EP 0952491 A2.

The intensity sensors of the intensity sensor device may correspond to the second facets in terms of their boundary shape and/or in terms of their surface area. A light loss as a result of overexposure of the second facets, i.e. insofar as illumination light is lost beyond the second facets, can then be similar in magnitude to a light loss as a result of overexposure of the intensity sensors. For example, a design can be achieved in which the sensor signal of the intensity sensors remains proportional to the intensity of the illumination light that arrives in the object field even if a light loss of the object field illumination, e.g. as a result of drifts of the EUV light source, is temporally variable.

Insofar as the illumination optical unit is designed such that a design of the second facets and for example the number and arrangement of the second individual mirrors respectively forming the second facets are variable depending on the illumination configuration, the assigned intensity sensors adapted to this size variability can likewise have a variable size or a variable boundary shape. Such a variable size or boundary shape of the intensity sensors can be achieved by specifying intensity sensors of different sizes. Alternatively or additionally, a variability of the size or the boundary shape of the intensity sensors can be achieved by stops respectively assigned to the intensity sensors in the illumination light beam path upstream of the intensity sensors and/or by a pixel design of the intensity sensors, wherein depending on the size and shape of the second facets, such pixelated intensity sensors are read only in each case for the sensor pixels which correspond in terms of their arrangement to the size or shape of the second facets.

In embodiments, the number of intensity sensors can be in the range of between 3 and 100. Such a number of intensity sensors can make possible, depending on the desired profile, a sufficient spatial resolution for the detection object field coordinate to be measured. When measuring a detection object field coordinate, the number of intensity sensors can be in the range of between 4 and 100, in the range of between 5 and 50, for example of the order of 10 or of the order of 25. Insofar as two field dimensions are measured, for example insofar as the far field, in which the first facet mirror is arranged, is intended to be measured with the aid of the intensity sensor device, the number of intensity sensors can also be greater than 100 and can be in the range of between 100 and 1000.

In embodiments, the intensity sensors can be arranged spatially adjacent to the second individual mirrors of the second facet mirror. Such an arrangement of the intensity sensors makes use of the fact that the illumination light in the region of the second individual mirrors is regularly present in facet-channelwise focused form, since there in the typical application the light source is at least approximately imaged into an arrangement plane of the second facet mirror. The arrangement of the intensity sensors adjacent to the second individual mirrors of the second facet mirror then can lead to the possibility of compactly arranging the intensity sensors next to one another.

In embodiments, the intensity sensors can be arranged as a sensor row. Such a sensor row can be particularly compact.

In embodiments, the sensor individual mirrors can be arranged on the first facet mirror in such a way that they cover the used region of the illumination light far field in two far field dimensions. Such an arrangement of the sensor individual mirrors can allow a 2D far field measurement, wherein the measurement positions of the sensor individual mirrors can serve as measurement support points, proceeding from which an extrapolation can then be effected for determining the entire 2D far field.

In an aspect, the disclosure provides a method for measuring a dependence of an intensity of the illumination light incident on the object field on at least one detection object field coordinate using an illumination optical unit according to the disclosure. The method comprises the following steps: assigning the individual mirrors of the first facet mirror of the illumination optical unit with respect to the individual-mirror groups of the first facet mirror forming the first facets to the second facets of the second facet mirror which image these individual-mirror groups at least into partial fields of the object field; selecting individual mirrors of the first facet mirror not used in the assignment as sensor individual mirrors of the intensity sensor device; coordinate assigning of the selected sensor individual mirrors to detection object field coordinates into which individual mirrors of the first facet mirror that are directly adjacent to the sensor individual mirrors are imaged into the object field; sensor assigning, depending on the coordinate assignment, of a respective one of the intensity sensors to the sensor individual mirror assigned to the respective detection object field coordinate, and guiding detection illumination light to the assigned intensity sensor via the sensor individual mirror assigned to the respective detection object field coordinate; and evaluating sensor data of the intensity sensors impinged on by the detection illumination light for the purpose of determining the dependence of the intensity of the illumination light incident on the object field on the at least one detection object field coordinate.

A method according to the disclosure can result in a relatively precise measurement of the dependence of the intensity of the illumination light on the detection object field coordinate, which can be carried out for example in parallel with used operation of the illumination optical unit. In order to prepare the evaluation step of the measuring method, the intensity sensors can be calibrated for example using an illumination arrangement with constant illumination intensity over the detection object field coordinate. The evaluation step can be followed by a correction step, in which an individual-mirror assignment or a facet assignment is changed in such a way that an actual value of an illumination intensity distribution over the detection object field coordinate approaches a target value. The resulting correction can be carried out for example in such a way that an illumination angle distribution of an illumination of the object field by the illumination optical unit remains unchanged on account of the correction.

In embodiments, a method can include selecting and assigning the sensor individual mirrors and evaluating the sensor data in such a way that a 2D far field measurement of the illumination light far field results from the evaluated sensor data.

Features of a method according to the disclosure can correspond to features of an illumination optical unit according to the disclosure.

In an aspect, the disclosure provides an illumination system comprising an illumination optical unit according to the disclosure and an EUV light source. In an aspect, the disclosure provides an optical system comprising an illumination optical unit according to the disclosure and a projection optical unit for imaging the object field into an image field. In an aspect, the disclosure provides a projection exposure apparatus comprising such an optical system as claimed and an EUV light source. In an aspect, the disclosure provides a method for producing a microstructured or nanostructured component, comprising the following method steps: providing a reticle; providing a wafer having a coating that is sensitive to the illumination light; projecting at least one portion of the reticle onto the wafer with the aid of such a projection exposure apparatus; and developing the light-sensitive layer exposed with the illumination light on the wafer. In an aspect, such a method can be used to make a semiconductor component in the form of a microchip, for example a memory chip. Features of such aspects can correspond to features of an illumination optical unit according to the disclosure.

A relatively precisely measured and, if appropriate, corrected illumination intensity distribution over the detection object field coordinate, this can give rise to the possibility of relatively precise and high-resolution component production. In a production method according to the disclosure, a measuring method can be used for example for specifying an optimized illumination setting.

### BRIEF DESCRIPTION OF THE DRAWINGS

Exemplary embodiments of the disclosure are explained in more detail below with reference to the drawing, in which:

FIG. 1 shows very schematically, in meridional section, a projection exposure apparatus for EUV microlithography, comprising a light source, an illumination optical unit and a projection optical unit, wherein a plan view of an object field of the projection exposure apparatus is illustrated in an insert;

FIG. 2 shows schematically and likewise in meridional section a beam path of selected individual rays of illumination light within the illumination optical unit according to FIG. 1, proceeding from an intermediate focus through to a reticle or object arranged in the object plane of the projection optical unit in the region of the illumination or object field;

FIG. 3 shows a plan view of a detail of a first facet mirror of the illumination optical unit of the projection exposure apparatus, wherein an individual-mirror group of the first facet mirror which forms a first facet is highlighted, which is imaged via individual mirrors of a second facet mirror of the illumination optical unit, which form a second facet, via a partial beam of the illumination light into the object field;

FIG. 4 shows, in an illustration similar to FIG. 3, a detail of a further embodiment of the first facet mirror, once again with a highlighted individual-mirror group which is imaged as a first facet via an assigned second facet of the second facet mirror into the object field;

FIG. 5 shows, in an illustration similar to FIGS. 3 and 4, a plan view of the first facet mirror with an arrangement of individual mirrors according to FIG. 4, wherein an allocation of the first facet mirror with first facets, each formed from individual-mirror groups, is illustrated, which are imaged into the object field while being superimposed on one another, wherein sensor individual mirrors of an intensity sensor device for measuring a dependence of an intensity of the illumination light incident on the object field on a detection object field coordinate are additionally highlighted between these individual-mirror groups;

FIG. 6 shows schematically and perspectively an embodiment of the illumination optical unit of the projection exposure apparatus comprising the first facet mirror and the second facet mirror, with illustration of an illumination light beam path between a light source and an intensity sensor of an intensity-sensor sensor row of the intensity sensor device, guided via one of the sensor individual mirrors of the first facet mirror;

FIG. 7 shows a diagram showing a correlation N_{G} (ordinate) of the field height coordinates x within a respective column of a columnwise assignment of the individual-mirror groups of a variant of the first facet mirror to field heights x of the object field of the first facet mirror (abscissa), when setting an illumination setting "y-dipole", wherein the assignment of the individual mirrors to the field heights x leads to a total of eight individual-mirror columns (j=1,…8);

FIG. 8 shows one example of a distribution of the sensor individual mirrors on a variant of the first facet mirror with a very much larger number of individual mirrors in comparison with FIG. 5, once again in a plan view;

FIG. 9 shows, in a diagram, a field height dependence of a target illumination intensity I_{SOLL} (dashed) over the object field and an as yet uncorrected actual illumination intensity I_{IST} (solid);

FIG. 10 shows, in an illustration similar to FIG. 9, intensity measurement values of the intensity sensors over the sensor row according to FIG. 6, with correction measurement values I^{K} (dashed) for the case of the target illumination intensity according to FIG. 9 and actual measurement values I^{M} (solid) for the case of the as yet uncorrected illumination intensity distribution according to FIG. 9; and

FIG. 11 shows a comparison of relative changes in the field height dependencies firstly in the case of the illumination with the actual illumination intensity according to FIG. 9 as a relative intensity deviation I_{IST} (dashed) and secondly as a relative measurement value deviation I_{IST}^{M} between the two measurement curves according to FIG. 10 (solid), in order to illustrate a measurement quality of the intensity sensor device which can be used for a subsequent correction.

### DETAILED DESCRIPTION

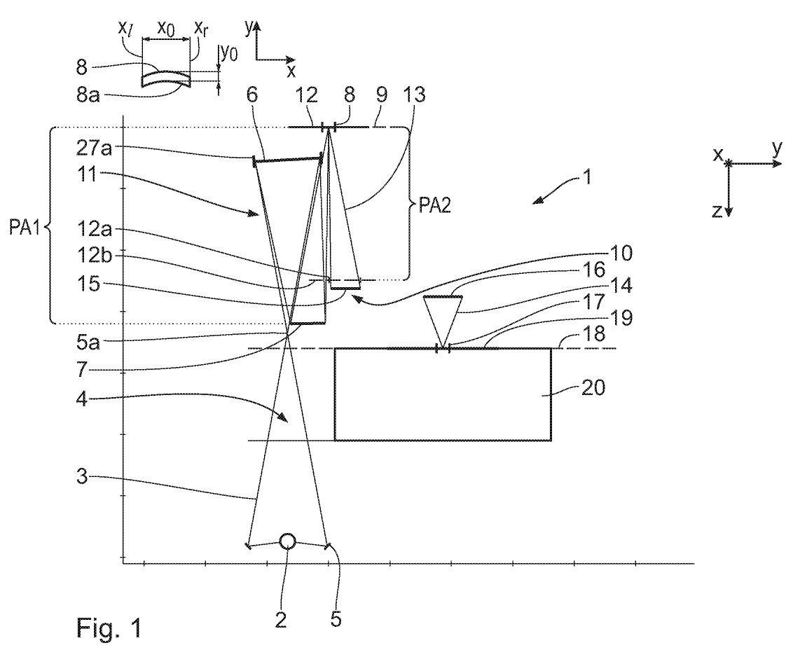

A microlithographic projection exposure apparatus 1 illustrated highly schematically and in meridional section in FIG. 1 has a light source 2 for illumination light 3. The light source 2 is an EUV light source which generates light in a wavelength range of between 5 nm and 30 nm. This can be an LPP (laser produced plasma) light source, a DPP (discharge produced plasma) light source or a synchrotron radiation-based light source, for example a free electron laser (FEL).

A transfer optical unit 4 is used to guide the illumination light 3, proceeding from the light source 2. The transfer optical unit has a collector 5, which is illustrated only with regard to its reflective effect in FIG. 1, and a transfer facet mirror 6, which is described in even greater detail below and which is also referred to as first facet mirror or as field facet mirror. An intermediate focus 5a of the illumination light 3 is arranged between the collector 5 and the transfer facet mirror 6. A numerical aperture of the illumination light 3 in the region of the intermediate focus 5a is NA = 0.182, for example. An illumination specification facet mirror 7, which is also referred to as second or further facet mirror and is likewise explained in even greater detail below, is disposed downstream of the transfer facet mirror 6 and thus the transfer optical unit 4. The optical components 5 to 7 are constituent parts of an illumination optical unit 11 of the projection exposure apparatus 1.

The transfer facet mirror 6 is arranged in a field plane of the illumination optical unit 11 in an illumination light far field of the light source 2.

The illumination specification facet mirror 7 of the illumination optical unit 11 is arranged at a distance from pupil planes of the illumination optical unit 11. Such an arrangement is also referred to as specular reflector.

In an alternative embodiment of the illumination optical unit, the second facet mirror 7 can also be arranged in a pupil plane of the illumination optical unit 11 and in this case is a pupil facet mirror.

An object to be illuminated in the form of a reticle 12 is disposed downstream of the illumination specification facet mirror 7 in the beam path of the illumination light 3, the reticle being arranged in an object plane 9 of a downstream projection optical unit 10 of the projection exposure apparatus 1. The projection optical unit 10 is a projection lens. The illumination optical unit 11 is used to illuminate an object field 8 on the reticle 12 in the object plane 9 in a defined manner. The object field 8 simultaneously constitutes an illumination field of the illumination optical unit 11. Generally it holds true that the illumination field is formed in such a way that the object field 8 can be arranged in the illumination field.

Like the transfer facet mirror 6 as well, the illumination specification facet mirror 7 is part of a pupil illumination unit of the illumination optical unit and serves to illuminate an entrance pupil 12a in a pupil plane 12b of the projection optical unit 10 with the illumination light 3 with a specified pupil intensity distribution. The entrance pupil 12a of the projection optical unit 10 can be arranged in the illumination beam path upstream of the object field 8 or else downstream of the object field 8. FIG. 1 shows the case in which the entrance pupil 12a is arranged in the illumination beam path downstream of the object field 8. A pupil distance PA between the second facet mirror 7 and the pupil plane 12b results in this case as the sum of a z-distance PA1 between the second facet mirror 7 and the object plane 9 and the z-distance PA2 between the object plane 9 and the pupil plane 12b. The following holds true in the z-direction: PA = PA1 + PA2. The pupil distance PA can also be measured in the beam direction.

In order to facilitate the representation of positional relationships, a Cartesian xyz-coordinate system is used hereinafter. The x-direction runs perpendicularly to the plane of the drawing into the latter in FIG. 1. The y-direction runs toward the right in FIG. 1. The z-direction runs downwards in FIG. 1. Coordinate systems used in the drawing have x-axes running parallel to one another in each case. The course of a z-axis of the coordinate systems follows a respective principal direction of the illumination light 3 within the respective figure under consideration.

The object field 8 has an arcuate or partly circular shape and is delimited by two mutually parallel circle arcs and two straight side edges which run in the y-direction with a length y₀ and are at a distance x₀ from one another in the x-direction. The aspect ratio x₀/y₀ is 13 to 1. An insert in FIG. 1 shows a plan view of the object field 8, this plan view not being true to scale. A boundary shape 8a is arcuate. In an alternative and likewise possible object field 8, the boundary shape thereof is rectangular, likewise with aspect ratio x₀/y₀.

The reticle 12 is displaced through the object field 8 along an object displacement direction y during a projection exposure.

The projection optical unit 10 is indicated only in part and highly schematically in FIG. 1. An object field-side numerical aperture 13 and an image field-side numerical aperture 14 of the projection optical unit 10 are illustrated. Further optical components (not illustrated in FIG. 1) of the projection optical unit 10 for guiding the illumination light 3 between indicated optical components 15, 16 of the projection optical unit 10 are situated between these optical components 15, 16, which can be embodied for example as mirrors that are reflective for the EUV illumination light 3.

The projection optical unit 10 images the object field 8 into an image field 17 in an image plane 18 on a wafer 19, which, like the reticle 12 as well, is carried by a holder (not illustrated in more specific detail). Both the reticle holder and the wafer holder are displaceable both in the x-direction and in the y-direction using corresponding displacement drives. An installation space of the wafer holder is illustrated as a rectangular box at 20 in FIG. 1. The installation space 20 is rectangular with an extent in x-, y- and z-directions that is dependent on the components to be accommodated herein. The installation space 20 has, for example, proceeding from the center of the image field 17, an extension of 1 m in the x-direction and in the y-direction. In the z-direction, too, the installation space 20 has, proceeding from the image plane 18, an extension of 1 m, for example. The illumination light 3 has to be guided in the illumination optical unit 11 and the projection optical unit 10 in such a way that it is in each case guided past the installation space 20.

The transfer facet mirror 6 has a multiplicity of transfer facets, which are also referred to as first facets. The transfer facet mirror 6 can be embodied as a MEMS mirror. The transfer facets are individual mirrors 21 which are switchable at least between two tilt positions and which are embodied as micromirrors. The individual mirrors 21 can be embodied as micromirrors tiltable in a driven manner about two rotation axes perpendicular to one another.

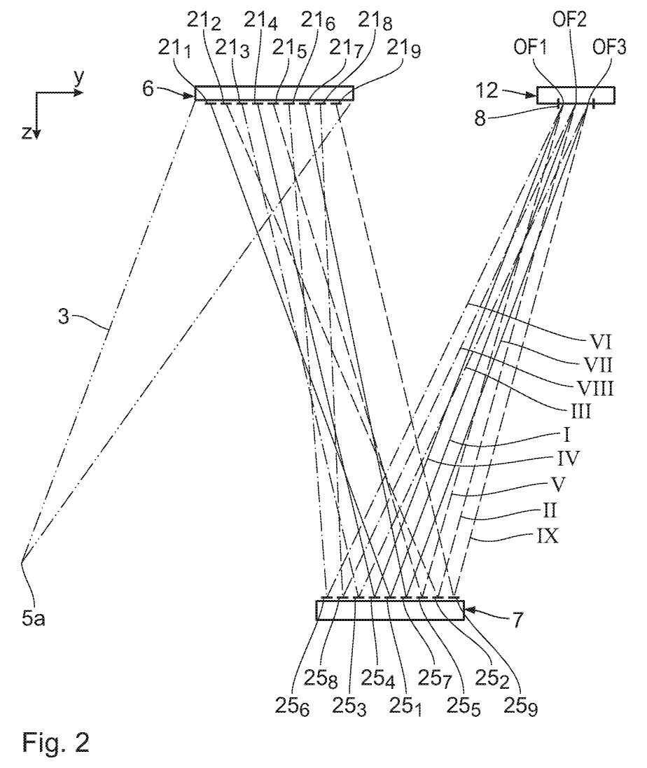

Of these individual mirrors 21, a row having a total of nine individual mirrors 21 is illustrated schematically in the yz-sectional view according to FIG. 2, the individual mirrors being indexed from left to right by 21₁ to 21₉ in FIG. 2. In actual fact, the transfer facet mirror 6 has a significantly greater multiplicity of the transfer facets 21. The transfer facets 21 are grouped into a plurality of transfer facet groups not illustrated in more specific detail in FIG. 2. These transfer facet groups are also referred to as individual-mirror groups, as virtual field facets or as virtual facet groups.

Each of the transfer facet groups guides a component of the illumination light 3, which is also referred to as an illumination light partial beam, via an illumination channel for partial or complete illumination of the object field 8. Via the illumination channel and an illumination light partial beam 3ᵢ (cf. the partial beams I to IX indicated in FIG. 2) guided via the channel, exactly one illumination specification facet 25 of the illumination specification facet mirror 7 is assigned in each case to one of the individual-mirror groups or transfer facet groups. In principle, each of the illumination specification facets 25 can for its part in turn be constructed from a plurality of individual mirrors. The illumination specification facets 25 are also referred to hereinafter as second facets.

For further details of possible embodiments of the transfer facet mirror 6 and the projection optical unit 10, reference is made to WO 2010/099 807 A.

At least some of the illumination specification facets 25 illuminate only a partial zone or partial field of the object field 8. The partial fields are shaped very individually and, moreover, depend on the desired illumination direction distribution (pupil shape) in the object field 8, i.e. the illumination setting. The illumination specification facets 25 are therefore illuminated by very differently shaped virtual field facets, the shape of which corresponds precisely to the shape of the respective partial field to be illuminated. Moreover, each illumination specification facet 25 contributes to different regions of the pupil depending on the location in the object field 8.

The illumination specification facet mirror 7 can be embodied as a MEMS mirror, especially if each of the illumination specification facets 25 is constructed from a plurality of individual mirrors. The illumination specification facets 25 are micromirrors switchable between at least two tilt positions. The illumination specification facets 25 are embodied as micromirrors which are tiltable in a driven manner about two mutually perpendicular tilt axes continuously and independently, i.e. the micromirrors can be positioned into a multiplicity of different tilt positions.

One example of a specified assignment of individual transfer facets 21 to the illumination specification facets 25 is illustrated in FIG. 2. The illumination specification facets 25 in each case assigned to the transfer facets 21₁to 21₉ are indexed according to this assignment. The illumination facets 25 are illuminated from left to right on the basis of this assignment in the order 25₆, 25₈, 25₃, 25₄, 25₁, 25₇, 25₅, 25₂and 25₉.

The indices 6, 8 and 3 of the facets 21, 25 include three illumination channels VI, VIII and III which illuminate three object field points OF1, OF2, OF3 from a first illumination direction, the object field points being numbered from left to right in FIG. 2. The indices 4, 1 and 7 of the facets 21, 25 pertain to three further illumination channels IV, I, VII which illuminate the three object field points OF1 to OF3 from a second illumination direction. The indices 5, 2 and 9 of the facets 21, 25 pertain to three further illumination channels V, II, IX which illuminate the three object field points OF1 to OF3 from a third illumination direction.

The illumination directions assigned to
the illumination channels VI, VIII, III,
the illumination channels IV, I, VII and
the illumination channels V, II, IX

are identical in each case. The assignment of the transfer facets 21 to the illumination specification facets 25 is therefore such that this results in a telecentric illumination of the object field 8 in the case of the illumination example illustrated pictorially.

The object field 8 can be illuminated via the transfer facet mirror 6 and the illumination specification facet mirror 7 in the style of a specular reflector. The principle of the specular reflector is known from US 2006/0132747 A1.

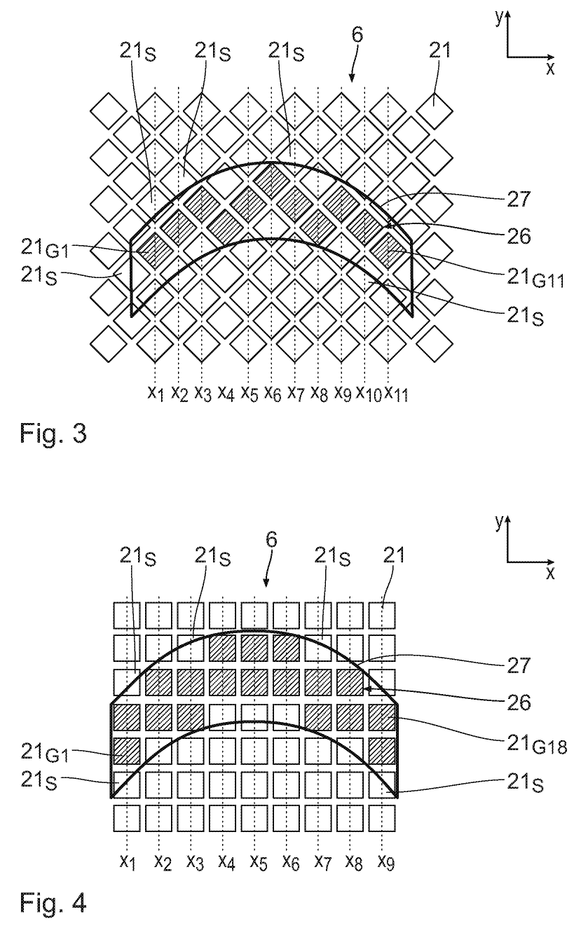

FIG. 3 schematically shows a plan view of a detail of the first facet mirror 6 comprising square first facets 21, which are arranged in an array tilted by 45° with respect to the xy-coordinate system. The rows and columns of this array arrangement thus run at an angle of 45° with respect to the x-direction and y-direction, respectively.

In FIG. 3, an individual-mirror group 26 comprising individual mirrors 21_{G1} to 21_{G11}is highlighted, which is imaged as a first facet via a respectively assigned second facet 25 of the second facet mirror 15 into the object field 8.

The individual mirrors 21_{Gi} of the individual-mirror group 26 lie within an arc-field-shaped group boundary 27 of the individual-mirror group 26. In actual fact, the number of individual mirrors 21_{Gi} belonging to a respective individual-mirror group 26 is significantly greater in practice and can be for example in the range of between 15 and 50 or even greater.

Some individual mirrors 21 of the first facet mirror 6 are only partially located within the group boundary 27. Here, a tilting of the respective individual mirror 21 by way of a corresponding control of the illumination optical unit 11 can be used to decide whether or not these individual mirrors 21 partially located in the group boundary 27 ought to belong to the individual-mirror group 26. For example, those individual mirrors 21 which are located with at least 60% of their reflection surface or, as indicated in FIG. 3, with at least 100% of their reflection surface within the group boundary 27 can be assigned to the individual-mirror group 26. In the region for example of a reflection surface proportion of 50% per individual mirror 21 located within the group boundary 27, there are some individual mirrors 21 which, given this selection criterion, cannot be assigned either to the individual-mirror group 26 highlighted in FIG. 3 or to an adjacent individual-mirror group, since the reflection surface of such individual mirrors 21 located on the limit of the group boundary 27 in the case of the group assignment illustrated reaches the minimum surface area limit within the respective group boundary 27 for no individual-mirror groups. Some of these individual mirrors 21 are highlighted as potential sensor individual mirrors 21_{S} in FIG. 3. As far as imaging of adjacent individual mirrors 21 into the object field 8 is concerned, such potential sensor individual mirrors 21_{S} are assigned to different field heights xᵢ of the individual-mirror group 26, i.e. different x-coordinates of the individual-mirror group 26 imaged into the object field 8. Such field heights xᵢ (i=1 to 11) are highlighted in FIG. 3. These potential sensor individual mirrors 21_{S} thus represent an illumination intensity of the illumination light far field, which regularly varies only slightly over the spatial coordinates x, y of the field facet mirror 6 along an individual-mirror extension and in which the field facet mirror 6 is arranged, at the location of a respective assigned field height xᵢ of a detection object field coordinate x.

These potential sensor individual mirrors 21_{S} are each directly adjacent to the group individual mirrors 21_{Gi} of the individual-mirror group 26.

FIG. 4 shows a variant of the first facet mirror 6 in an illustration similar to FIG. 3. Components and functions corresponding to those which have already been explained above with reference to FIGS. 1 to 3, and for example with reference to FIG. 3, bear the same reference signs and will not be discussed in detail again.

The field facet mirror 6 according to FIG. 4 has an array arrangement of the individual mirrors 21 that is untilted relative to the xy-coordinate system. The rows and columns of this array arrangement thus run in the x-direction and in the y-direction.

The group individual mirrors 21_{Gi} (i=1 to 18) are once again highlighted in FIG. 4. In the arrangement according to FIG. 4, too, once again some potential sensor individual mirrors 21_{S} and their field heights xᵢ (i=1 to 9) are highlighted.

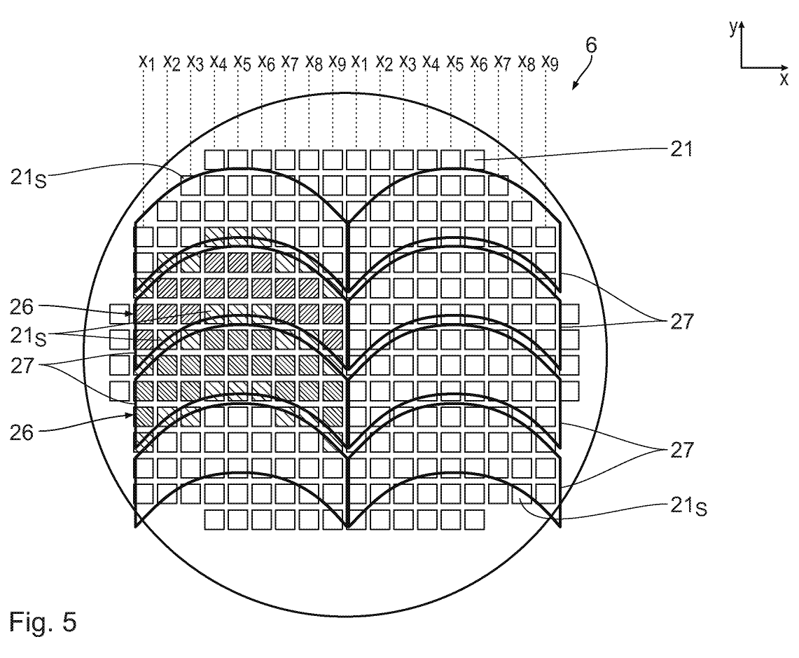

FIG. 5 shows a typical allocation of one embodiment of the field facet mirror 6 with individual-mirror groups 26 with respective group boundaries 27. In the case of the assignment according to FIG. 5, these individual-mirror groups 26 are arranged in two columns each of four individual-mirror groups 26 in the style of the individual-mirror group according to FIG. 4. FIG. 5 illustrates that between each two individual-mirror groups 26 that are adjacent in one of the columns there are sensor individual mirrors 21_{S} at each of the field heights x₁ to x₉ which belong to none of the individual-mirror groups 26. A corresponding allocation analogous to FIG. 5 results for an arrangement of the individual mirrors 21 that is tilted with respect to the xy-coordinate axes according to FIG. 3.

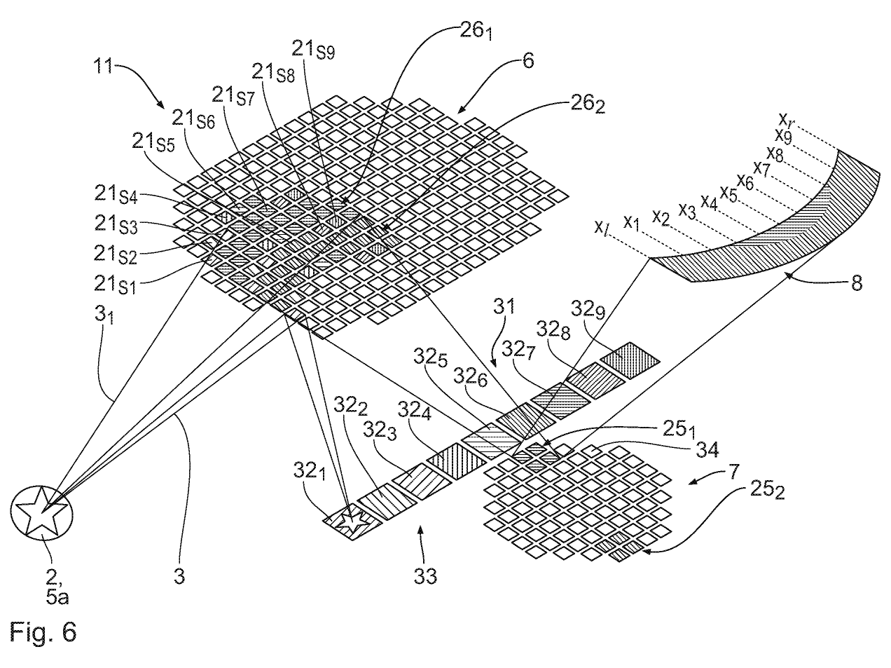

FIG. 6 shows, in a perspective, schematic view, main components of, firstly, the illumination optical unit 11 and, secondly, an intensity sensor device 31 for measuring a dependence of an intensity of the illumination light 3 incident on the object field 8 on the detection object field coordinate x. The intensity sensor device 31 includes selected sensor individual mirrors 21_{Si} constituted from potential sensor individual mirrors 21_{S} which arise from individual mirrors 21 of the field facet mirror 6 which are not able to be used for the individual-mirror groups 26, as already explained above with reference to FIGS. 3 to 5. Furthermore, the intensity sensor device 31 includes a plurality of intensity sensors 32₁ to 32₉arranged in the form of a sensor row 33 spatially adjacent to the individual mirrors 34 of the second facet mirror 7. In comparison with individual mirrors 34 of the second facet mirror 34, the intensity sensors 32ᵢ are illustrated with exaggerated size in FIG. 6. The intensity sensors 32ᵢ correspond to the second facets 25 in terms of shape and surface area. This ensures that the light loss as a result of overexposure of the second facets 25 is similar in magnitude to that as a result of overexposure of the intensity sensors 32ᵢ and thus the sensor signal remains proportional to the intensity in the object field 8, even if the light loss, e.g. as a result of a drifting source plasma, is temporally variable.

If the second facets 25 are not physical facets of fixed size, but rather virtual facets in the form of groups of second individual mirrors 34, the second facets 25 will have different shapes and sizes depending on the application. In this case, the intensity sensors 32ᵢ can also have a variable size. This can be achieved via a larger number of sensors of different sizes, additional stops upstream of the sensors, or via pixelated sensors which are read only in part.

FIG. 6 illustrates a light path of the illumination light 3 which is guided from the light source 2 or the intermediate focus 5a via one of the sensor individual mirrors 21_{S}, specifically a sensor mirror of the type 21_{S1}, to the assigned intensity sensor 32₁.

Corresponding guidance of an illumination light partial beam 3₁ from the light source 2 or the intermediate focus 5a via the individual-mirror group 26₁and the second facet 25₁to the object field 8 is also indicated schematically.

In FIG. 6, corresponding hatchings are used to highlight two individual-mirror groups 26₁and 26₂in the style of the individual-mirror groups 26 according to FIGS. 4 and 5, which are imaged into the object field 8 while being superimposed on one another via associated second facets 25₁, 25₂. In the design illustrated, the second facets 25ᵢ each consist of a 2x2 array of the individual mirrors 34 of the second facet mirror 7. In practice, a second facet 25ᵢ can also consist of exactly one individual mirror 34 or else can be constructed from a different number of the individual mirrors 34, for example as a 3x3, as a 4x4, as a 5x5 array, as a 6x6 array or else as a 7x7 array.

As in the case of the individual-mirror group 26 according to FIGS. 4 and 5, in the case of the illumination optical unit 11 according to FIG. 6 as well, the individual-mirror groups 26 there, which are imaged into the object field 8 while being superimposed on one another, are exactly nine individual mirrors 21 wide in the x-direction. These nine individual mirrors 21 are assigned to the field heights x₁ to x₉. Each of the individual-mirror groups 26 thus comprises individual mirrors 21 from nine individual-mirror columns 1 to 9 situated next to one another. According to this nine-column subdivision of the individual-mirror groups 26 and the following field height assignment, this results in a type classification of the sensor individual mirrors 21_{S1} to 21_{S9}selected for impinging on the intensity sensors 32₁to 32₉.

The sensor individual mirrors of the type 21_{S1} are individual mirrors 21 which are arranged in the same column as the individual mirrors 21 are arranged in the first, left column of the respective individual-mirror group 26. The sensor individual mirrors of the type 21_{S1} thus belong to the field height x₁.

Accordingly, the further types of sensor individual mirrors 21_{S2}, 21_{S3}, … belong to individual mirrors 21 of the field facet mirror 6 which are arranged in the same columns as the individual mirrors 21 in the second, third, … columns of the respective individual-mirror group 26. These further sensor individual mirrors of the types 21_{S2}, 21_{S3},... thus belong to the field heights x₂, x₃,…

This nine-column subdivision of the individual-mirror groups 26 and the sensor individual mirrors 21_{Si} enables a spatial resolution of a measurement of the dependence of the intensity of the illumination light 3 incident on the object field 8 into nine field height portions x₁ to x₉ between a left edge xₗ and a right edge xᵣ of the object field 8. These nine field height portions x₁ to x₉are illustrated for the object field 8 in FIG. 6. Imaging results in an image inversion when the individual-mirror groups 26 are imaged into the object field 8 while being superimposed on one another, such that the object field 8 in FIG. 6 appears curved in the opposite direction in comparison with the individual-mirror groups 26.

The intensity sensors 32ᵢ are arranged within the sensor row 33 in the order of their assignment to the types 21_{Si} of the sensor individual mirrors. This row order of the intensity sensors 32ᵢ is not mandatory, rather just the assignment of the intensity sensors 32ᵢ to the types of the sensor individual mirrors 21_{Si}, i.e. to the field height portions x₁ to x₉ respectively measurable by way of the latter, is to be known.

A measure of the intensity of the field height portion x₁ of the detection object field coordinate x arranged on the left can thus be determined by way of the sensor individual mirrors of the type 21_{S1} and the assigned intensity sensor 32₁. The same applies, mutatis mutandis, to the sensor individual mirrors of the types 21_{S2} to 21_{S9} and the intensity sensors 32₂ to 32₉ assigned to the field height portions x₂ to x₉. With the aid of the entire sensor row 33, the intensity sensors 32ᵢ of which obtain the illumination light 3 of the respective types 21_{Si}, the detection object field coordinate x can thus be measured over the entire object field 8 with regard to the illumination light intensity respectively incident there.

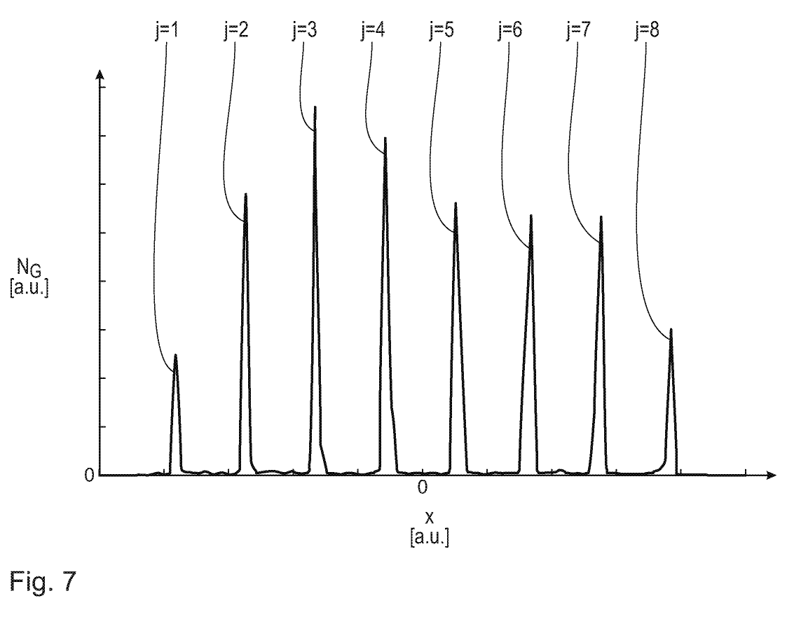

FIG. 7 shows an assignment correlation of the individual-mirror groups 26ᵢ with respect to individual-mirror columns on the field facet mirror 6. FIG. 7 shows the case – differing from the schematic arrangement according to FIG. 5 and 6 – that a total of 8 columns of individual-mirror groups 26ᵢ^{j} (j = 1 to 8) are arranged on the facet mirror 6. The dependence of a number N_{G} of the individual-mirror groups 26ᵢ^{j} versus a spatial coordinate x of the field facet mirror 6 is illustrated. According to the eight-column arrangement, individual-mirror groups 26ᵢ^{j} are present at the x-positions of the eight columns j=1 to j=8.

For the case of a field facet mirror 6 comprising a very much larger number of individual mirrors 21, this case differing from the schematic illustration according to FIGS. 3 to 6, FIG. 8 shows a distribution of potential sensor individual mirrors 21_{S} over an entire mirror surface of the first facet mirror 6. The illustration shows a selection of potential sensor individual mirrors 21_{S} for specific x-field positions, namely for a total of five exemplary x-field positions (left field edge (x=xₗ), field center (x=0), right field edge (x=xᵣ) and two more x-positions between the left field edge and the center (x=xₗ/2) and between the center and the right field edge (x=xᵣ /2).

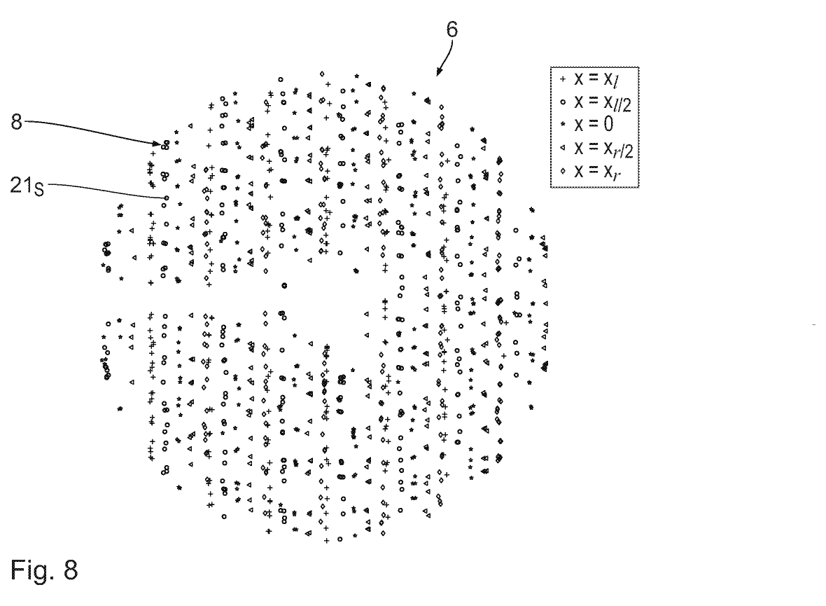

With regard to the large number of individual-mirror groups 26ᵢ^{j} , a good statistical distribution of sensor individual mirrors 21_{Si} which can be used for the intensity device 31 results given a distribution of the potential sensor individual mirrors 21_{S} according to FIG. 8. For each of these sensor individual mirrors 21_{S}, on account of the assignment of the adjacent individual mirrors 21 of the field facet mirror 6 to the respective individual-mirror groups 26ᵢ^{j}, this results in the x-coordinate for which the respective sensor individual mirror 21_{S} is representative upon the illumination of the object field 8 by the individual-mirror groups 26ᵢ^{j} adjacent to this sensor individual mirror 21_{Si}. Accordingly, the respective sensor individual mirror 21_{S} can be assigned to one of the sensor individual-mirror types 21_{Si}, for example the types 21_{S1} to 21_{S9} explained above in association with FIG. 6.

Depending on the achievable spatial resolution over the potential sensor individual mirrors 21_{S}, the number of intensity sensors 32ᵢ of the intensity sensor device 31 can also be smaller or larger. This number i can be in the range of between 3 and 100.

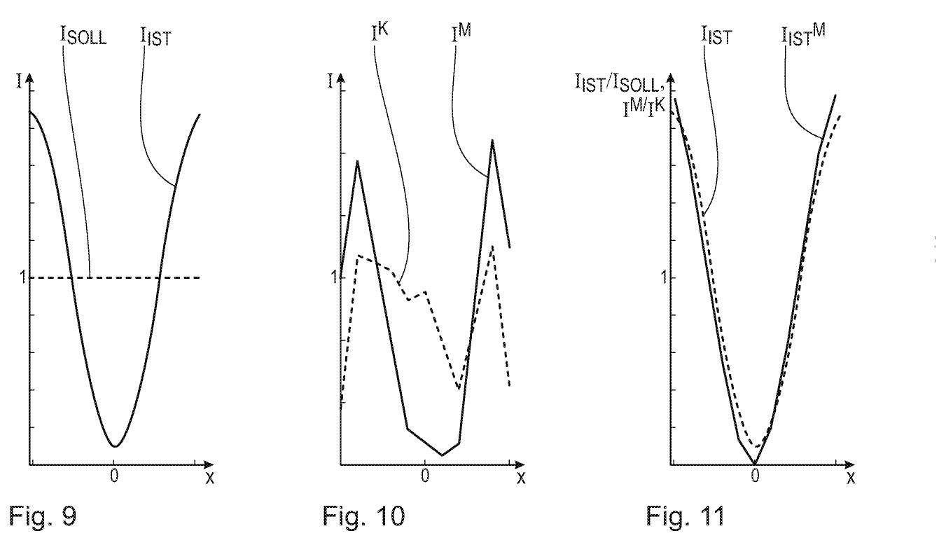

FIGS. 9 to 11 illustrate a measurement precision of the intensity sensor device 31 in the case of an illumination light intensity greatly dependent on the detection object field coordinate x.

FIG. 9 shows by way of example as a dashed line a desired target intensity distribution I_{SOLL}, which is constant over the complete x-coordinate of the object field. FIG. 9 illustrates as a solid line an exemplary actual intensity distribution I_{IST}, which has a cosine distribution by way of example over the x-coordinate of the object field 8 and, likewise by way of example, is larger (more intensive) than the intensity I_{SOLL} by about 10% in the range of the maxima and smaller (less intensive) than the intensity I_{SOLL} by about 10% in the range of the cosine minimum.

FIG. 10 shows as a dashed line correction measurement results I^{K} for the intensity sensors 32ᵢ (i=1 to 9) assigned to the respective x-coordinate of the object field 8, i.e. to the respective field height, for the constant illumination intensity distribution I_{SOLL} according to FIG. 9. The x-positions measured by the respective intensity sensors 32ᵢ on account of the assignment to corresponding sensor individual mirrors 21_{Si} are indicated by the digits "1" to "9" on the x-axis in FIG. 10. The dashed, measured correction intensity profile I^{K} of the intensity sensors 32ᵢ over the x-coordinate is not constant, unlike the constant illumination intensity I_{SOLL} over this object field coordinate x. This is in line with practice where a cumulative intensity impingement or a number of the different types 21_{Si} to 21_{S9} need not be constant. In the realistic case illustrated in FIG. 10, for example, relatively few sensor individual mirrors of the types 21_{S1}, 21_{S7} and 21_{S9} are present, so that the intensity values measured there are comparatively small in comparison with the other measurement values. These dashed correction measurement values I^{K} in FIG. 10 serve as a calibration curve of the intensity sensor device 31. This calibration curve can be determined for example by measurement of a projection exposure apparatus in which it is ensured in some other way that the object field 8 is illuminated with homogeneous illumination intensity distribution in accordance with the distribution I_{SOLL}.

The measurement value I^{M} of the intensity sensors 32₁ to 32₉for the illumination intensity profile I_{IST} according to FIG. 9 is plotted as a solid line in FIG. 10. A comparison of the dashed curve with the solid curve in FIG. 10, even without calculation of the relative changes, reveals that the actual intensity distribution I_{IST} is less illumination-intensive than the target distribution I_{SOLL} in the region of the middle x-coordinates and more intensive in the region of the left and right x-coordinate edges.

FIG. 11 shows formation of a ratio of the measurement values I^{M} and I^{K} depicted as solid and dashed lines in FIG. 10 as a solid ratio measurement result I_{IST}^{M}, i.e. the measurement values I^{M} from FIG. 10 illustrated as a solid line and normalized to the dashed correction values I^{K}. In comparison therewith, FIG. 11 again illustrates, as a dashed line, the actual illumination intensity distribution I_{IST} over the detection object field coordinate x, i.e. in principle the same curve that was illustrated as a solid line in FIG. 9. In contrast to FIG. 9, the illumination intensity distribution I_{IST} is plotted as a ratio value with respect to the target intensity distribution I_{SOLL} in FIG. 11.

The vertical axis in FIG. 11 thus represents the ratio I^{M}/I^{K} or I_{IST} /I_{SOLL}.

FIG. 11 shows the good correspondence between the measured actual value I_{IST}^{M} and the in fact actual value I_{IST}of the illumination intensity distribution over the detection object field coordinate x of the object field 8.

A deviation between these two curves I_{IST} andI_{IST}^{M} can be at most of the order of 3%, of the order of 2.5%, of the order of 2%, or even smaller still.

In addition, the sensor individual mirrors 21_{S}, as illustrated in FIG. 8, can be selected in such a way that they cover the used region of the illumination light far field in the two far field dimensions x and y over the entire field facet mirror 6.

On account of this coverage of the used region of the illumination light far field in the two far field dimensions x and y by the arrangement of the usable sensor individual mirrors 21_{S}, it is possible to measure the far field of the light source in the arrangement plane of the field facet mirror 6 in two dimensions x and y completely via a corresponding embodiment of the intensity sensor device 31. Such an embodiment of the intensity sensor device 31 then has a larger number of intensity sensors 32^{j}ᵢ which cover the two-dimensionality of the far field measurement. Such an intensity sensor device can have for example intensity sensors 32ᵢ^{j} arranged in an array comprising j rows and i columns. Since, as already explained above in connection with the sensor row 33, just the assignment of the positions of the respective sensor individual mirrors 21_{S} to the respective intensity sensors 32ᵢ^{j} is to be known, an array arrangement of the intensity sensors 32ᵢ^{j} need not correspond to the arrangement of the sensor individual mirrors 21_{S} used for measurement.

Measuring the dependence of the intensity of the illumination light 3 incident on the object field 8 on the detection object field coordinate x involves firstly assigning the individual mirrors 21 of the first facet mirror 6 of the illumination optical unit 11 with respect to individual-mirror groups 26ᵢ of the first facet mirror 6 to the second facets 25ᵢ of the second facet mirror 7 which image these individual-mirror groups 26ᵢ at least into partial fields of the object field 8.

Individual mirrors 21 of the first facet mirror 6 which are not used in this assignment are subsequently selected. These selected, unused individual mirrors 21 are selected as sensor individual mirrors 21_{S} of the intensity sensor device 31.

This is subsequently followed by coordinate assigning of the selected sensor individual mirrors 21_{S} to the respective detection object field coordinate xᵢ into which individual mirrors 21 of the first facet mirror 6 that are directly adjacent to the sensor individual mirrors 21_{S} to be assigned are imaged into the object field 8. This corresponds to an assignment of the respective sensor individual mirror 21_{S} to a sensor individual-mirror type 21_{Si}, as explained above.

This is then followed by assigning, depending on the coordinate assignment performed, of a respective one of the intensity sensors 32ᵢ to the sensor individual mirror 32_{Si} assigned to the respective detection object field coordinate xᵢ.

Part of the illumination light 3 is then guided as detection illumination light to the assigned intensity sensor 32ᵢ via the sensor individual mirror 21_{Si} assigned to the respective detection object field coordinate or to the field height portion xᵢ. This can be done in parallel with the projection exposure. This is then followed by evaluating sensor data of the intensity sensors 32ᵢ impinged on by the detection illumination light for the purpose of determining the dependence of the intensity I_{IST} of the illumination light 3 incident on the object field 8 on the at least one detection object field coordinate x.

This sensor data evaluation can be followed by a correction of the intensity dependence of the illumination intensity on the detection object field coordinate x, for example by modifying an assignment of the individual mirrors 21 of the first facet mirror 6 to the respective individual-mirror groups 26ᵢ or by modifying an assignment of the individual-mirror groups 26ᵢ to the second facets 25ᵢ.

The projection exposure can be effected in parallel with the measurement or else after an appropriate correction.

Selecting and assigning the sensor individual mirrors 21_{S} and evaluating the sensor data can be effected in such a way that a 2D far field measurement results from the evaluated sensor data. The respective data of the selected and assigned sensor individual mirrors 21_{S} can form support points of a measurement far field, between which the entire measurement far field is then inferred by extrapolation.

In order to produce a microstructured component, for example a highly integrated semiconductor component, for example a memory chip, with the aid of the projection exposure apparatus 1, firstly the reticle 12 and the wafer 19 are provided. Subsequently, a structure on the reticle 12 is illuminated by the illumination light 3 using the illumination optical unit 11 and is projected onto a light-sensitive layer on the wafer 19 using the projection optical unit of the projection exposure apparatus 1. By developing the light-sensitive layer, a microstructure is then produced on the wafer 19 and the microstructured or nanostructured component is produced therefrom.

The component produced can be a microchip, for example a memory chip.

What is claimed is:

1. An illumination optical unit, comprising:
a first facet mirror comprising first individual mirrors configured to reflectively guide illumination light from an EUV light source, the first individual mirror configured to be arranged in a used region of an illumination light far field;
a second facet mirror configured to reflectively guide the illumination light reflected from the first facet mirror to an object field; and
an intensity sensor,
wherein:
the second facet mirror comprises second individual mirrors defining second facets which, via partial beams of the illumination light, image individual-mirror groups of the first facet mirror defining first facets at least into partial fields of the object field;
the intensity sensor device is configured to measure a dependence of an intensity of the illumination light incident on the object field on at least one detection object field coordinate; and
the intensity sensor device comprises:
a plurality of the first individual mirrors constituting sensor individual mirrors of the first facet mirror; and
a plurality of intensity sensors;
the sensor individual mirrors are assigned to a plurality of different object field positions along the detection object field coordinate; and
the sensor individual mirrors are configured to reflectively guide the illumination light to the intensity sensors.

2. The illumination optical unit of claim 1, wherein the plurality of intensity sensors comprises between 3 and 100 intensity sensors.

3. The illumination optical unit of claim 1, wherein the intensity sensors are adjacent to the second individual mirrors.

4. The illumination optical unit of claim 1, wherein the intensity sensors are in a row.

5. The illumination optical unit of claim 1, wherein the sensor individual mirrors cover the used region of the illumination light far field in two far field dimensions.

6. The illumination optical unit of claim 1, wherein the plurality of intensity sensors comprises between 3 and 100 intensity sensors, and the intensity sensors are adjacent to the second individual mirrors.

7. The illumination optical unit of claim 6, wherein the intensity sensors are in a row.

8. The illumination optical unit of claim 7, wherein the sensor individual mirrors cover the used region of the illumination light far field in two far field dimensions.

9. The illumination optical unit of claim 6, wherein the sensor individual mirrors cover the used region of the illumination light far field in two far field dimensions.

10. The illumination optical unit of claim 1, wherein the plurality of intensity sensors comprises between 3 and 100 intensity sensors, and the intensity sensors are in a row.

11. The illumination optical unit of claim 10, wherein the sensor individual mirrors cover the used region of the illumination light far field in two far field dimensions.

12. The illumination optical unit of claim 1, wherein the plurality of intensity sensors comprises between 3 and 100 intensity sensors, and the sensor individual mirrors cover the used region of the illumination light far field in two far field dimensions.

13. A system, comprising:
an illumination optical unit according to claim 1; and
an EUV light source,
wherein the system is an illumination system.

14. A system, comprising:
an illumination optical unit according to claim 1; and
a projection optical unit configured to image the object field into an image field,
wherein the system is an optical system.

15. An apparatus, comprising:
an optical system, comprising:
an illumination optical unit according to claim 1; and
a projection optical unit configured to image the object field into an image field; and
an EUV light source,
wherein the apparatus is a projection exposure apparatus.

16. An apparatus, comprising:
an optical system, comprising:
an illumination optical unit according to claim 1; and
a projection optical unit configured to image the object field into an image field; and
an EUV light source,
wherein the apparatus is a projection exposure apparatus, and plurality of intensity sensors comprises between 3 and 100 intensity sensors.

17. An apparatus, comprising:
an optical system, comprising:
an illumination optical unit according to claim 1; and
a projection optical unit configured to image the object field into an image field; and
an EUV light source,
wherein the apparatus is a projection exposure apparatus, and the intensity sensors are adjacent to the second individual mirrors.

18. A method of producing a component using a projection exposure apparatus comprising an illumination optical unit and a projection optical unit, the method comprising:
using the illumination optical system to illuminate a reticle in an object field of the projection optical unit with illumination light;
using the projection optical unit to project at least a portion of the illuminated reticle onto a material that is sensitive to the illumination light, the material being in an image field of the projection optical unit; and
developing the material,
wherein the illumination optical unit is an illumination optical unit according to claim 1, and the component is a microstructured component or a nanostructured structured component.

19. A method, comprising:
providing an illumination optical unit according to claim 1;
assigning the individual mirrors of the first facet mirror with respect to the individual-mirror groups of the first facet mirror defining forming the first facets to the second facets of the second facet mirror which image these individual-mirror groups at least into partial fields of the object field;
selecting individual mirrors of the first facet mirror not used in the assignment as sensor individual mirrors of the intensity sensor device;
coordinate assigning the selected sensor individual mirrors to detection object field coordinates into which individual mirrors of the first facet mirror that are directly adjacent to the sensor individual mirrors are imaged into the object field;
sensor assigning, depending on the coordinate assignment, a respective one of the intensity sensors to the sensor individual mirror assigned to the respective detection object field coordinate, and guiding detection illumination light to the assigned intensity sensor via the sensor individual mirror assigned to the respective detection object field coordinate; and
evaluating sensor data of the intensity sensors impinged on by the detection illumination light to determine a dependence of the intensity of the illumination light incident on the object field on the at least one detection object field coordinate.

20. The method of claim 19, further comprising selecting and assigning the sensor individual mirrors and evaluating the sensor data to provide a two dimensional far field measurement of the illumination light far field.
